(19) United States
(12) Patent Application Publication
(10) Pub. No.: US 2012/0234371 A1
(43) Pub. Date: Sep. 20, 2012

(54) INCIDENT ANGLE DEPENDENT SMART SOLAR CONCENTRATOR

(76) Inventors: Tong Zhang, Oxon (GB); Martin David Tillin, Oxon (GB); Takayuki Yuasa, Oxford (GB)

(21) Appl. No.: 13/051,656

(22) Filed: Mar. 18, 2011

(51) Int. Cl. H01L 31/052; E06B 7/00; H01L 31/0232

(52) U.S. Cl. 136/246; 438/72; 52/173.3; 257/E31.127

(57) ABSTRACT

A transparent solar concentrator is provided for converting solar energy into electrical energy. The solar concentrator includes a first light transmissive substrate, a plurality of solar cells for receiving solar energy and converting the solar energy into electrical energy, the plurality of solar cells positioned relative to the first substrate, and a plurality of light redirecting elements arranged in the first light transmissive substrate. Each of the plurality of light redirecting elements is configured to direct light incident on a first side of the first light transmissive substrate to a respective one of the plurality of solar cells on an opposite side of the first light transmissive substrate.

### TECHNICAL FIELD

The present invention relates to a low ratio solar concentrating device and system and, more particularly to a device and system in which a concentration ratio varies as a function of solar declination angle. Further, the invention relates to a method of design and manufacture of such device and system.

### BACKGROUND TO THE INVENTION

Photovoltaic (PV) panels are becoming increasingly important as a source of renewable energy and low carbon energy generation. There is a trend to incorporation of PV panels with building structures, so called Building Integrated PV (BIPV). In particular there is a desire to incorporate PV panels within windows so that a window could perform the function of a window and at the same time generate energy. A problem with this approach is that there is a trade-off between the requirement for light to pass through the window and at the same time generate electricity. Nevertheless, panels of this type already exist. Problems with such panels include they generally have a low transmittance and they create visible artifacts that affect the primary performance as a window. The reason for the low transmittance is usually that PV windows are made by making strips of PV cell with gaps between, and in order to maximize the power generated the ratio of PV cell area to gap area is made small.

What a smart PV window needs is a variable concentration ratio so that the light can be guided more to the solar cell when it is needed, i.e., around noon when the sun is high and irradiance is high, and allow light to pass through the window at other times. As used herein, the concentration ratio is defined as the ratio of light absorbed by PV cells (also known as solar cells) to light passing through the concentrator. Some prior art exists that attempts to solve this problem by making the power generation vary as a function of the solar declination angle (incident angle of the sun on the window). Whilst the solutions described below achieve this function, they only partially meet the requirements. They, however, also have the problem of being difficult and expensive to manufacture due to the design features that make the ideas unpractical.

US patent 2009/0255568 A1 (Morgan Solar Inc., Oct. 15, 2009) explains a system in which a plurality of solar cells are fabricated on ridged surfaces of the substrate such that the light impinging a PV window at the pre-determined viewing angle is directed and concentrated to solar cells with an incident angle dependent concentration ratio. The issues associated with this system include difficulties of solar fabrication on the ridged surface, and poor see-through quality when used for window type applications.

US patent 2008/0257403 (R. Edmonds, Oct. 23, 2008) suggests an idea to fabricate solar cell strips incorporated within the body of a window glass such that the active area of the solar cell is nearly perpendicular to the glass surface. This design does provide an incident angle dependent performance. It does not, however, concentrate the light. It is also difficult to fabricate the solar cell within the substrate.

### SUMMARY OF INVENTION

A first aspect of the invention present invention provides an incident angle dependent transparent solar concentrator including: at plurality of PV cells arranged on a substrate; a plurality of light redirecting elements (e.g., slits) in a substrate wherein the refractive index of a substance in the light redirecting elements is lower than that of the substrate, the plurality of light redirecting elements aligned with the plurality of PV cells.

When light is incident normal to the substrate containing the light redirecting elements some of the light is absorbed by the PV cells and other light passes through the substrate. When light is incident non-normal to the substrate then some of the light that would have passed through the structure is totally internally reflected (TIR) by the plurality of light redirecting elements and is absorbed by the plurality of PV cells. In this way, proportionally more light is absorbed by the plurality of PV cells as the incident angle increases, up to a maximum value determined by the physical parameters of the device.

The plurality of light redirecting elements may be arranged such that they do not penetrate completely through the substrate in which they exist.

The plurality of light redirecting elements may be arranged such that there is one light redirecting element aligned with one PV cell.

The plurality of light redirecting elements may be fabricated in the same substrate on which the plurality of PV cells is fabricated.

The plurality of light redirecting elements may be fabricated in a different substrate to that on which the PV cells are fabricated.

The plurality of light redirecting elements may include air.

The plurality of light redirecting elements may include a material that has a refractive index which is different but lower than the substrate in which they exist.

The plurality of light redirecting elements may be made with the sides of the light redirecting elements being non-parallel.

The substrates containing the plurality of light redirecting elements and plurality of PV cells may be laminated between other substrates so as to provide environmental protection from damage, humidity and UV radiation.

According to a different aspect of the invention, the plurality of light redirecting elements may be arranged such that there is more than one light redirecting element arranged to align with one PV cell, and the plurality of light redirecting elements do not penetrate completely through the substrate in which they exist.

According to a different aspect of the invention, the plurality of PV cells may include more than one type of PV cell, in order to receive different wavelengths of radiation.

According to a different aspect of the invention, the plurality of light redirecting elements are not perpendicular to the substrate in which they exist.

According to a different aspect of the invention, the plurality of light redirecting elements may be of a different depth in the substrate in which they exist, dependent on the position along the substrate.

According to a different aspect of the invention, the plurality of light redirecting elements may be fabricated from both sides of the substrate in which they exist.

The plurality of light redirecting elements on one side of the substrate may by aligned with the plurality of light redirecting elements on the opposite side of the substrate.

According to a different aspect of the invention, the interfaces between the plurality of light redirecting elements and the substrate are different with one interface comprising an optically flat interface and the other comprising a rough interface.

According to a different aspect of the invention, the incident angle solar concentrator can include part of a window.

According to one aspect of the invention, a transparent solar concentrator includes: a first light transmissive substrate; a plurality of solar cells for receiving solar energy and converting the solar energy into electrical energy, the plurality of solar cells positioned relative to the first substrate; a plurality of light redirecting elements arranged in the first light transmissive substrate, each of the plurality of light redirecting elements configured to direct light incident on a first side of the first light transmissive substrate to a respective one of the plurality of solar cells on an opposite side of the first light transmissive substrate.

According to one aspect of the invention, the first light transmissive substrate has a first refractive index, and the plurality of light redirecting elements have a second refractive index, the second refractive index being less than the first refractive index.

According to one aspect of the invention, each of the plurality of light redirecting elements include a strip or groove arranged in the first light transmissive substrate, the strip or groove filled with a medium having a refractive index corresponding to the second refractive index.

According to one aspect of the invention, the medium is air.

According to one aspect of the invention, the plurality of solar cells are formed as a plurality of photovoltaic strips, each strip spaced apart from an adjacent strip by a predetermined distance.

According to one aspect of the invention, each light redirecting element is aligned with a respective one of the photovoltaic strips.

According to one aspect of the invention, the transparent solar concentrator further includes a second light transmissive substrate, and the plurality of light redirecting elements are formed in the first light transmissive substrate, and the plurality of solar cells are positioned relative to the second light transmissive substrate.

According to one aspect of the invention, the plurality of light redirecting elements do not penetrate completely through the first light transmissive substrate.

According to one aspect of the invention, the plurality of light redirecting elements include a first part having a reflecting surface and a second part having a reflecting surface, wherein the reflecting surface of the first part is offset from the reflecting surface of the second part.

According to one aspect of the invention, the plurality of light redirecting elements have an upper surface and a lower surface, and the upper and lower surfaces are non-parallel to each other.

According to one aspect of the invention, at least two light redirecting elements are assigned to a respective one of the plurality of solar cells

According to one aspect of the invention, the plurality of solar cells include a first type of solar cell configured to convert light having a first range of wavelengths into electrical energy, and a second type of solar cell configured to convert light having a second range of wavelengths into electrical energy, the second range different from the first range.

According to one aspect of the invention, a reflecting surface of the plurality of light redirecting elements is not perpendicular to an outside light-receiving face of the first light transmissive substrate.

According to one aspect of the invention, the plurality of light redirecting elements include first and second light redirecting elements, the first light redirecting element extending into the first light transmissive substrate to a first depth, and the second light redirecting element extending into the at least one substrate to a second depth, wherein he first and second depths are different from one another.

According to one aspect of the invention, the first and second depths correspond to a location of the respective light redirecting element within the first light transmissive substrate.

According to one aspect of the invention, at least one surface of the light redirecting element includes an optically flat surface and another surface of the light redirecting element includes an optically rough surface.

According to one aspect of the invention, the transparent solar concentrator further includes first and second outer light transmissive substrates, wherein the first light transmissive substrate is arranged between the first and second outer light transmissive substrates.

According to one aspect of the invention, a window system includes: a first outer light transmissive substrate and a second outer light transmissive substrate; and a transparent solar concentrator as described herein, wherein the solar concentrator is arranged between the first and second outer light transmissive substrates.

According to one aspect of the invention, the plurality of solar cells are patterned to provide an image.

According to one aspect of the invention, a method for creating a solar concentrator, includes: arranging a plurality of solar cells relative to a light transmissive substrate; forming a plurality of light redirecting elements in the light transmissive substrate, wherein respective ones of the plurality of light redirecting elements are positioned relative to respective ones of the plurality of solar cells so as to direct light incident on a first side of the light transmissive substrate to a respective one of the plurality of solar cells on an opposite side of the light transmissive substrate.

### ADVANTAGES OF THE INVENTION

In accordance with the present invention, it is possible to simply make an incident angle solar concentrator in which the concentration ratio of the concentrator increases as the angle of incidence increases from a normal direction in one way, and decreases as the angle of incidence increases negatively from the normal direction in the other way.

The device and system in accordance with the present invention have good potential for application to BIPV (Building Integrated PV). At the time when the sun is low, i.e., early morning and evening time, and especially in the winter, more light passes through the PV window and illuminates the interior of a building. This is the time when most light is needed in a building. In the middle of the day when the sun is high and irradiance rises, there will be more light absorbed by the PV cell. This will generate more electricity that would be possible with no incident angle concentration. In addition, there is less solar radiation entering the interior of the building and therefore solar gain is less; this will lower the cooling requirements of the building resulting in significant energy saving.

The device and method in accordance with the present invention can also be used for mobile devices that are (partially) powered by PV, in that the mobile devices do not need to be fully covered by PV cells but will still generate enough power to trickle charge a battery.

### BRIEF DESCRIPTION OF DRAWINGS

FIG. 1 is a schematic illustration of total internal reflection of light within a media.

FIG. 2 is a schematic drawing illustrating a cross section of a see-through PV window with two simply traced rays. (a) is a conventional see-through PV; (b) illustrates a concept in accordance with the present invention showing some of the light that in the conventional PV window would miss the PV cell will take TIR at the air slit and then hit the PV cell.

FIG. 3a is an exemplary 3D schematic drawing of the concept in accordance with the present invention.

FIG. 3b is a simulation result of the optical efficiency vs. incident angle for a device in accordance with the present invention. The optical efficiency is defined as the percentage of the incident light hitting the solar cell.

FIGS. 4a and 4b are exemplary schematic drawings of a ray trace result for an embodiment in accordance with the present invention that utilizes a group of small air slits instead of a single long air slit.

FIG. 5 is an exemplary schematic drawing of an embodiment in accordance with the invention that has multiple solar cell strips in one section to collect light with different spectrums.

FIGS. 6a and 6b are exemplary schematic drawings of the PV window cross section with tapered shaped air slits in accordance with the present invention.

FIGS. 7a and 7b are exemplary schematic drawings of the PV window cross section with tilted air slits in accordance with the present invention.

FIG. 8 is an exemplary schematic drawing of the PV window cross section with air slits that have one surface roughed in accordance with the present invention.

FIG. 9 is an exemplary schematic drawing of a PV window cross section in which the PV cells are fabricated on a separate substrate in accordance with the present invention.

FIG. 10 is an exemplary 3D schematic drawing showing the definition of the aspect ratio of the air slit in accordance with the present invention.

FIG. 11 is an exemplary 3D schematic drawing showing the substrate and slit cross section with the slits formed from low refractive index layers in a substrate with higher refractive index in accordance with the present invention.

FIG. 12 is an exemplary schematic drawing showing the PV window with varied length of slits in accordance with the present invention.

FIG. 13 is an exemplary schematic drawing of a substrate with slits fabricated in both sides of the substrate in accordance with the present invention.

FIG. 14 is an exemplary schematic drawing showing the tracing results of an assembly of the optical element and the solar cell that is fabricated on a separated substrate, with protective glass sheets in accordance with the present invention.

FIG. 15 is an exemplary schematic drawing showing the tracing results of an alternative assembly of the optical element and the solar cell that is fabricated on a separated substrate, with protective glass sheets in accordance with the present invention.

FIG. 16a is an exemplary schematic drawing showing the tracing results of an assembly of the optical element and the solar cell that is fabricated on a separated substrate in which the solar cell is patterned to show an image in accordance with the present invention.

FIG. 16b schematically shows an exemplary image produced by the device of FIG. 16a.

### DESCRIPTION OF REFERENCE NUMERALS

1. light beams (1a: the beam that misses the solar cell; 1b: the beam that hits the solar cell; 1a′: the beam that is reflected by the slit then reaches the solar cell; 1h: the light reaching the window in wide incident angle; 1l: the light reaching the window in small incident angle; 1a and 1b are the light beam that hit two separated slits)
2. substrate of the solar concentrator; 2′ is a light receiving surface of the substrate 2; 2s is a second substrate of solar cell
3. solar cells or solar cell strips (3a and 3b are different types of solar cell; 3s refers to solar strips in different dimension from solar cells 3)
4. slit (4s: the group of smaller slits; 4n and 4p show the slits with tapered shape cross section, 4z and 4y show the slits tilted in the different angle; 4s and 4ss mean the slit in different length; 4a and 4b are the split two shorter slits that perform effectively the same as one long/standard slot); 4′ and 4″ are upper and lower surfaces of the slits; 4a and 4b are reflective surfaces of the slits
5. roughed surface
6. substrate of the solar cell
7. w and h are the thickness and width of the slit, respectively
8. outer protective substrate
9. opaque electrodes of the solar cells
10. solar module
11. solar cell panel
12. decoration pattern

### DETAILED DESCRIPTION OF INVENTION

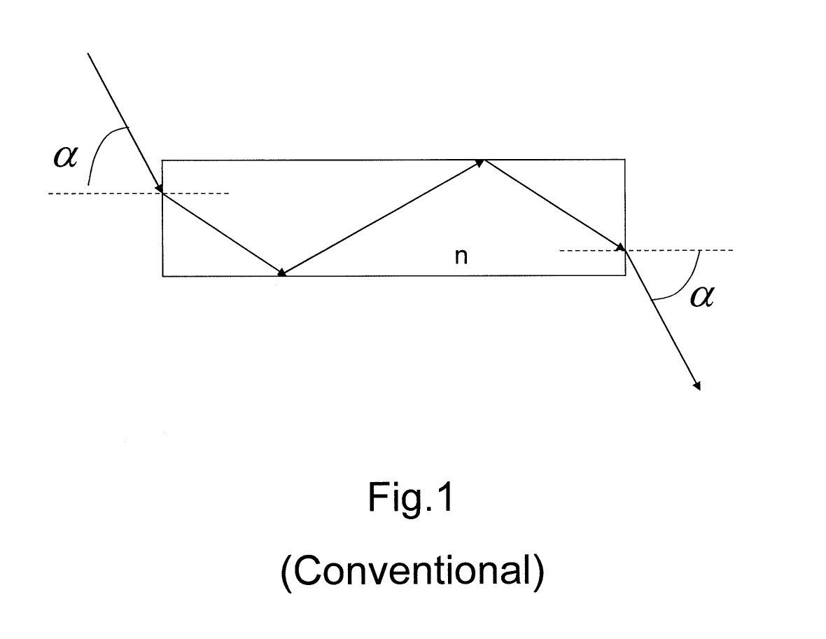

Total internal reflection (TIR) is an optical phenomenon that occurs when a ray of light strikes a medium boundary from higher refractive index media to lower refractive index media at an angle larger than a particular critical angle with respect to the normal to the surface. When TIR occurs, no light can pass through boundary and all of the light is reflected. The critical angle is the angle of incidence above which the total internal reflection occurs. FIG. 1 shows TIR within a cubic media that if the refractive index of the media n is greater than 1/(sin 45)=1.414 and the surrounding media is air (refractive index is 1), then even if the incident angle α is close to 90 degrees, the light will always be trapped inside the media until it reaches the opposite surface.

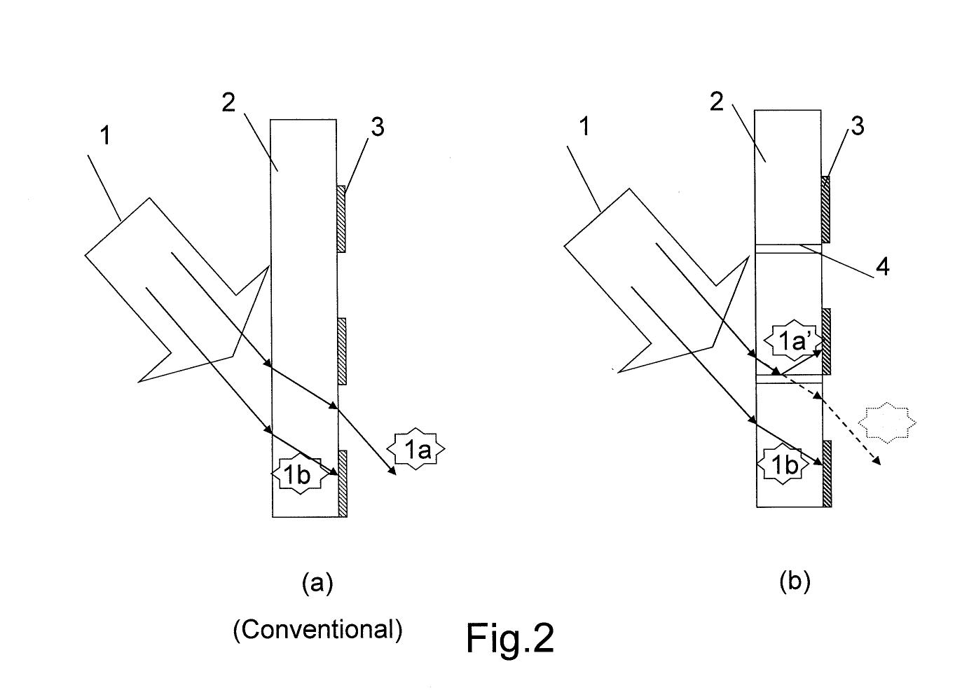

Most conventional see-through PV windows, such as the PV window shown in FIG. 2a, are made by fabricating patterned solar cells 3 on a clear substrate 2 so that one can see through the gap between the solar cells. Light 1 impinging on the surface of the substrate 2 can be viewed as multiple beams 1a and 1b. Beam 1a shows the light that misses the solar cell and 1b shows the light 1 that hits the solar cell. The percentage of the light 1 that hits the solar cell 3 is fixed by the solar cell area ratio regardless the incident angle.

In accordance with the present invention and as shown in FIG. 2b, a solar concentrator includes a first light transmissive substrate 2, a plurality of solar cells 3 (which may be arranged as a plurality of photovoltaic strips spaced apart from adjacent strips by a predetermined distance) positioned relative to the first substrate 2, and a plurality of light redirecting elements, e.g., slits 4, arranged in the first substrate 2. The light redirecting elements are positioned to be aligned with respective ones of the solar cells 3 (or strips of solar cells), and are configured to direct light incident on a first side of the first substrate 2 to a respective one of the plurality of solar cells 3 arranged on an opposite side of the first substrate 2. Therefore the light 1a′ that in the PV window according to FIG. 2a would have missed the solar cell 3 is now reflected by TIR and then is absorbed by the solar cell 3. At the same time, the light 1b that remains unchanged (i.e., it strikes the solar cell 3). As a result, more light can be collected by the solar cells 3 compared to the system without slits.

As used herein, a light redirecting element is a device that alters a direction of light incident on the light redirection element. The light redirection element is preferably formed via strips or grooves formed in the substrate 2, and can be filled with air or other media to provide a relatively lower refractive index so as to achieve total internal reflection. Thus, the solar concentrator can include a substrate 2 that has a first refractive index and light redirecting elements 4 that have a second refractive index, where the second refractive index is less than the first refractive index.

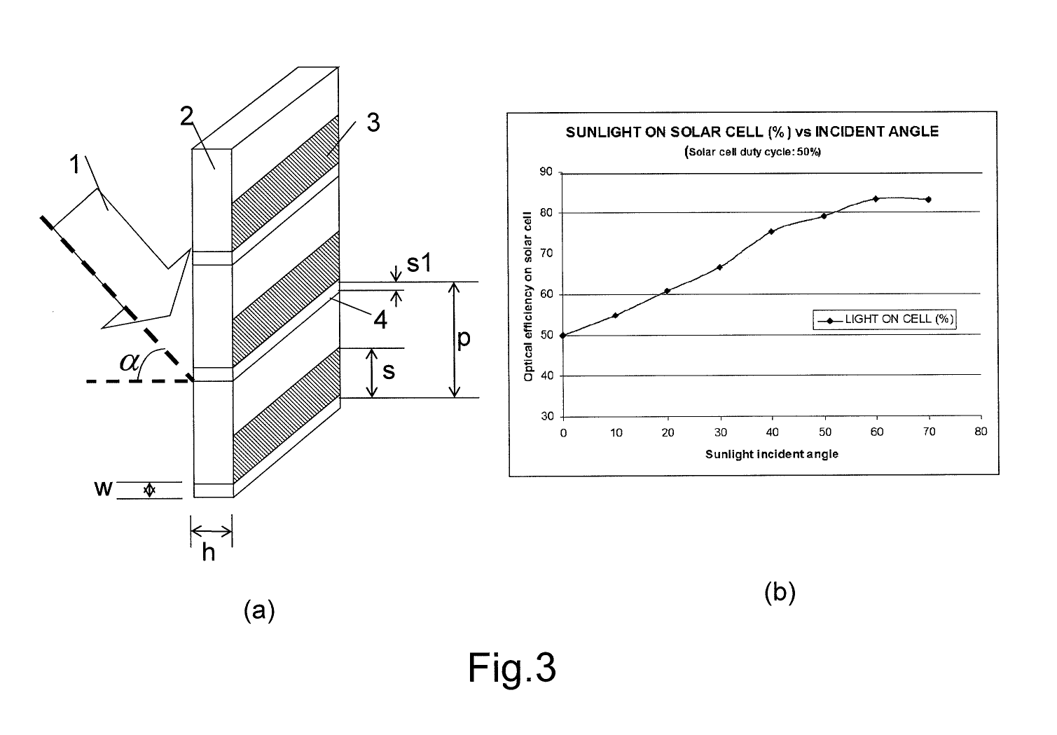

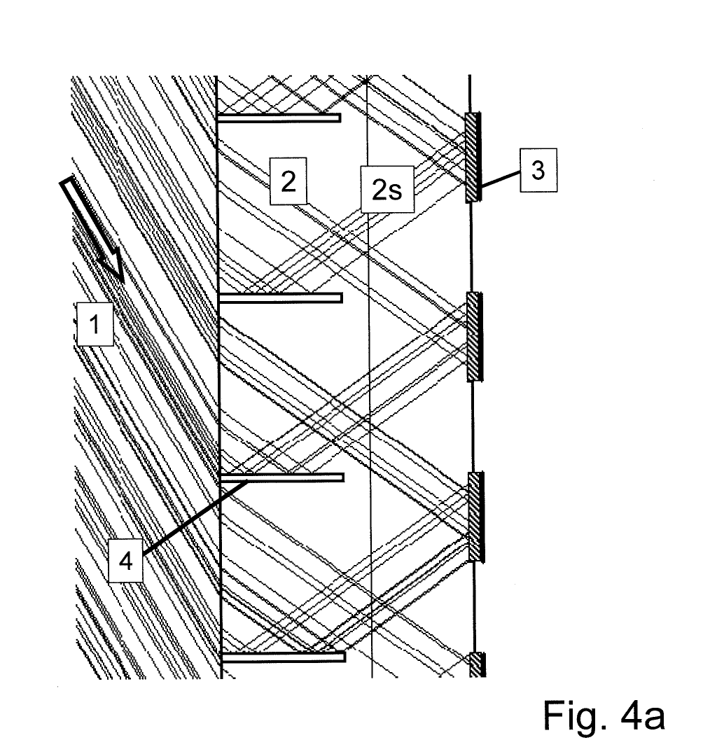

FIG. 3a is a 3D schematic drawing of a concept in accordance with the present invention, and FIG. 3b illustrates the simulation results of the optical efficiency vs. incident angle for a PV window in accordance with the present invention. Note that the solar cell area ratio, i.e., the ratio of s/p (where s is the width of the solar cell strip and p is the pitch of the solar cell strips on the substrate 2), is 50% as it is shown in FIG. 3a and zero degree incident means the light is incident at the normal angle. The optical efficiency here is defined as the percentage of the incident light hitting the solar cell 3. When the width of the solar cell strip s is equal to the depth h of the slit 4, the simulation shows the performance of this system in FIG. 3b. The results in FIG. 3b describe that when the light is incident at the normal angle the optical efficiency is 50%, but when the incident angle increases, there will be more light collected by the solar cell 3 due to the TIR from the slits 4. When the incident angle is close to 60-70 degrees, and the slits 4 include air as the medium, then over 80% of the light will hit the solar cell 3 even though the solar cell area ratio is only 50%. Note that for different dimension specifications, e.g., the ratio of w/h, h/s, and s/p, the shape of the curve in FIG. 3b will vary and the maximum efficiency will occur at a different incident angle.

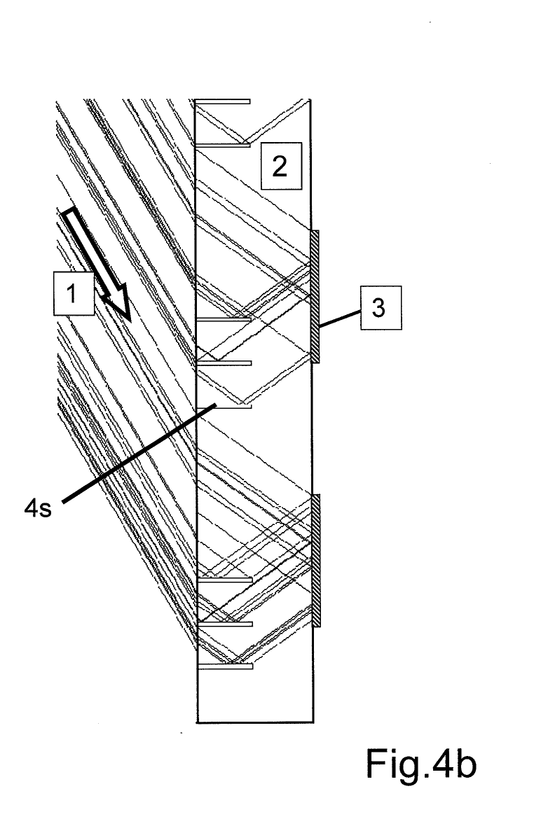

The slits 4 do not need to penetrate all the way through the substrate on which they are formed, and this is shown FIG. 4a. In FIG. 4a, the solar cell 3 is fabricated on a separated substrate 2s that has the same refractive index with the substrate 2 (thus the solar concentrator of FIG. 4a includes at least two substrates). The slits 4 can include multiple smaller slits 4s, wherein two or more of the group of slits 4s correspond or are assigned to one solar cell 3 as shown in FIG. 4b, and the device will still perform similar to the device of FIG. 4a. The slits 4s can have a depth and/or width that is less than the depth h and/or width s1 of the slits 4 in FIG. 4a. Advantages of this design shown in FIG. 4b include the potential ease of manufacture, as the depth of the slits 4s is shallower. Also, the device of FIG. 4b may gain some mechanical performance such as enhanced panel strength.

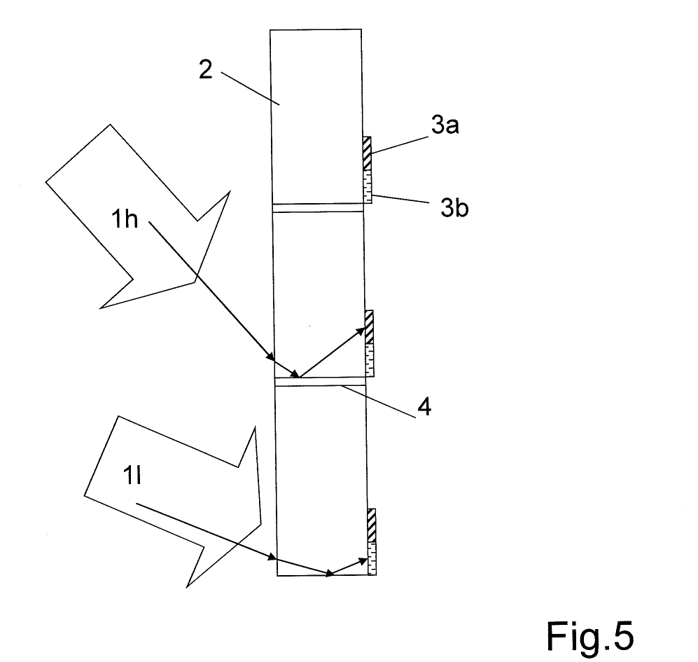

FIG. 5 shows a schematic drawing of an embodiment that has multiple solar cell types in one section, e.g., a first solar cell strip including a first type of solar cell 3a and a second solar cell strip including a second type of solar cell 3b. This configuration can be used to collect light with different spectrums (e.g., solar cell 3a converts light in a first range of wavelengths into electrical energy, while solar cell 3b converts light in a second range of wavelengths into electrical energy, the second range different from the first range). This idea is for the case where light from wider incident angles 1h has a different spectrum from light from low angle so that one can use different solar cells to capture light with different spectrums to increase the conversation efficiency of the system.

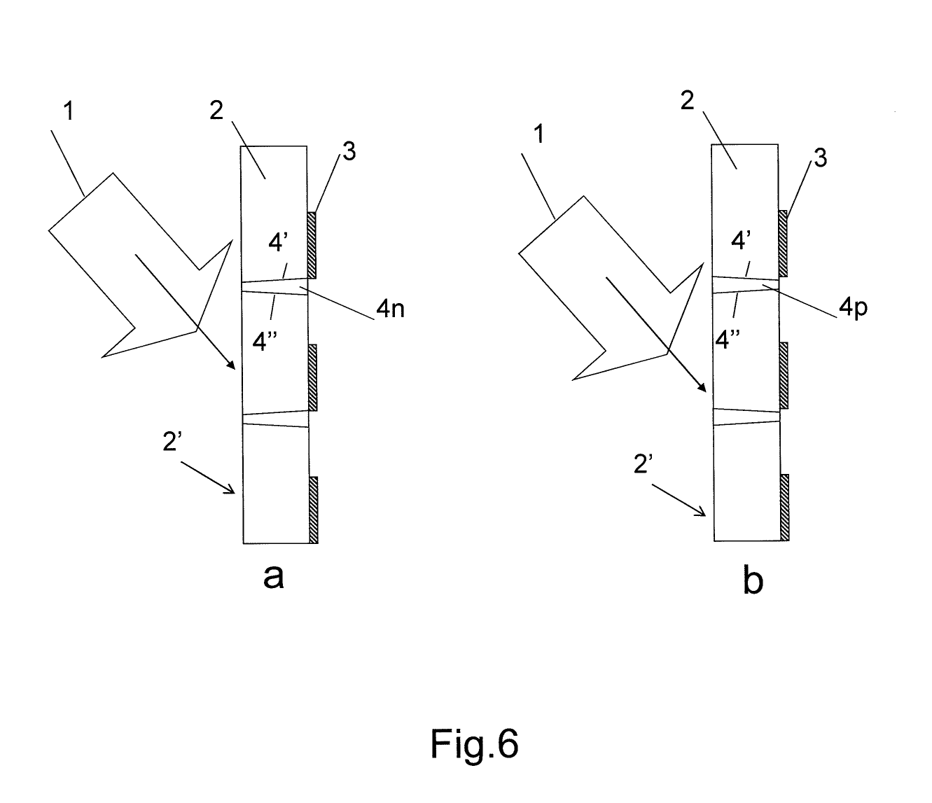

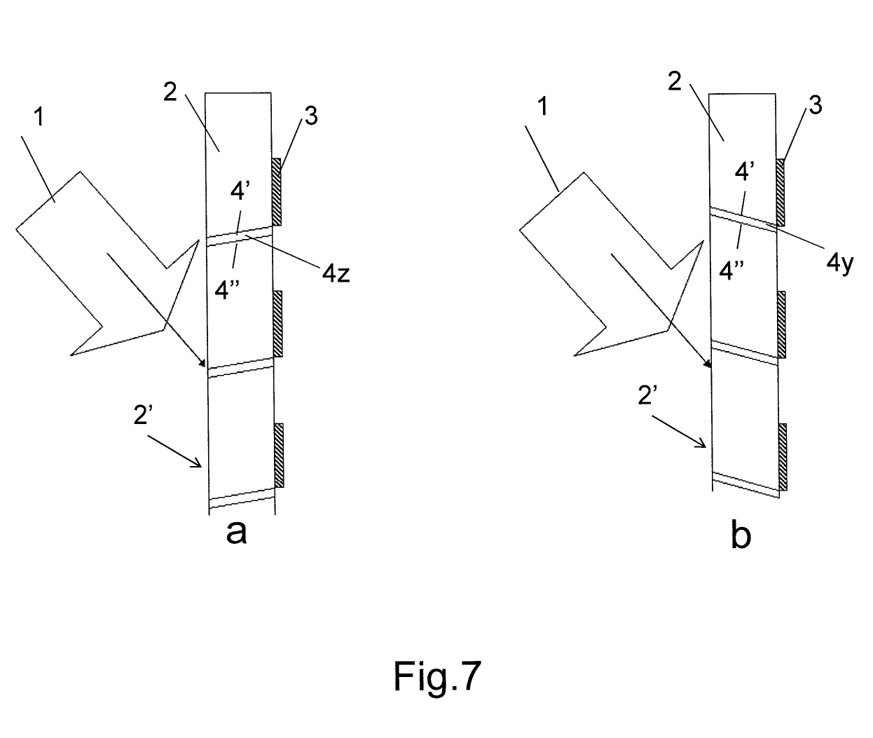

The simulation result shown in FIG. 3b has the peak optical efficiency at about 60-70 degrees incident angle. If we need to change the shape of the curve, apart from changing the detailed dimension ratio of the design, FIGS. 6 and 7 also show a few other options. The tapered air slits shown in FIGS. 6a and 6b provide a possible easier way of manufacturing the substrate 2 with slits 4n (tapered toward the incoming light 1) and 4p (tapered away from the incoming light 1) if an injection molding process is used. The configuration in FIGS. 4a and 4b results in upper and lower surfaces 4′ and 4″ of the slits 4 not being parallel to one another. An advantage of such configuration is that when the optical element is fabricated by, say injection molding method, a tapered mold would be easier to take off. The surface of the slits 4n does not necessarily need to be flat but can be curved e.g., a partial parabola. FIGS. 7a and 7b show the slits 4z and 4y angled relative to a light receiving face of the substrate. An advantage of this configuration is that by tilting the slits one can have more control of the optical performance, i.e. redirecting the light. In both FIGS. 6 and 7, the reflecting surface of the slits 4 is not perpendicular to the light receiving face 2′ of the substrate 2.

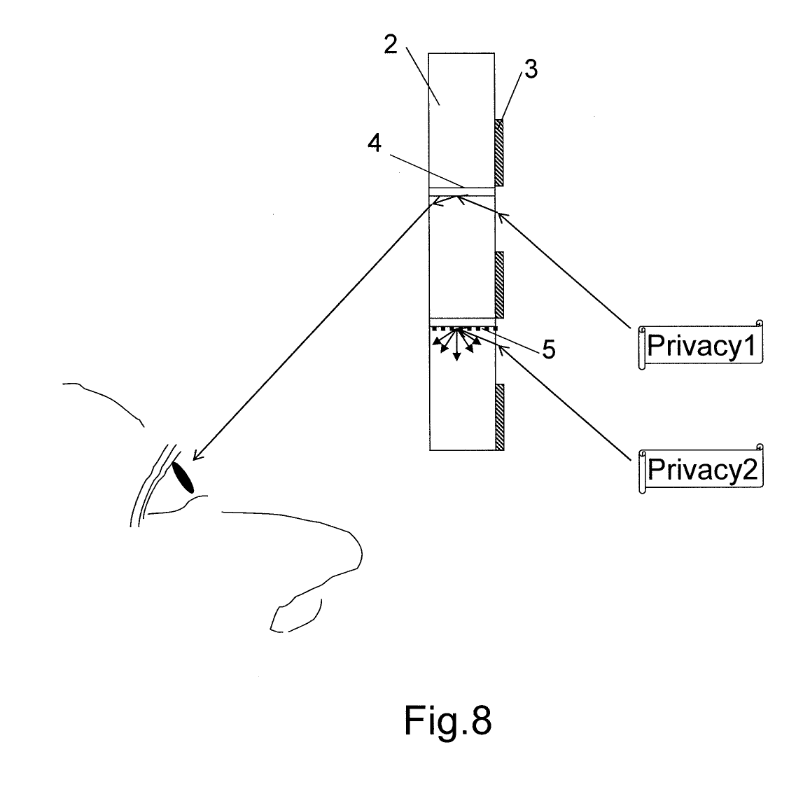

In many cases of window applications, privacy is quite important. People in a room appreciate more sunlight entering the room or generating more electricity from the solar cell, but they do not want people outside the building to see inside. A privacy feature is illustrated in FIG. 8 in which ‘Privacy1’ would be visible to people outside by virtue of TIR from the lower surface of the slit 4. The solution is also shown in FIG. 8 for the ‘Privacy2’ by roughening the lower surface 5 of the air slit 4 (e.g., one surface of the lit is optically flat, and the other surface of the slit is optically rough. As used herein, a “rough surface” is a surface having a roughness greater than 10 times the wavelength of the light, or the surface does not provide any recognizable reflected (or transmitted) picture. Therefore light from the room will be scattered rather than imaged to outside, and it will not be possible for people outside to see into the interior.

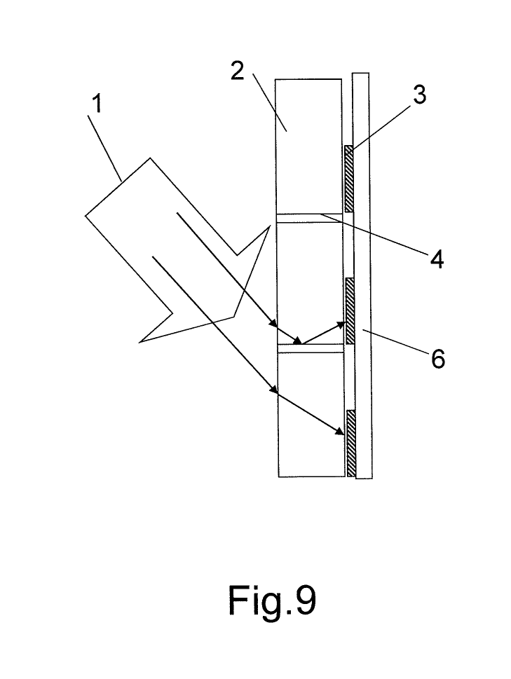

FIG. 9 shows one of the possible ways to assemble a PV window. The optical structure comprising the substrate 2 and slits 4 can be separated from the solar cell 3 that is fabricated on a separate substrate 6. In this way, the current standard see-through solar cell manufacture facility can be used directly to make the device in accordance with the invention without a large change to the process.

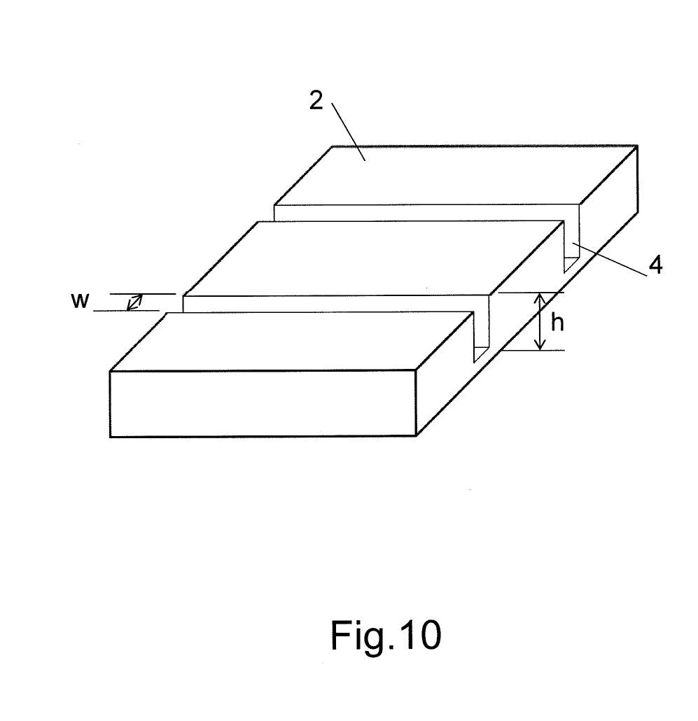

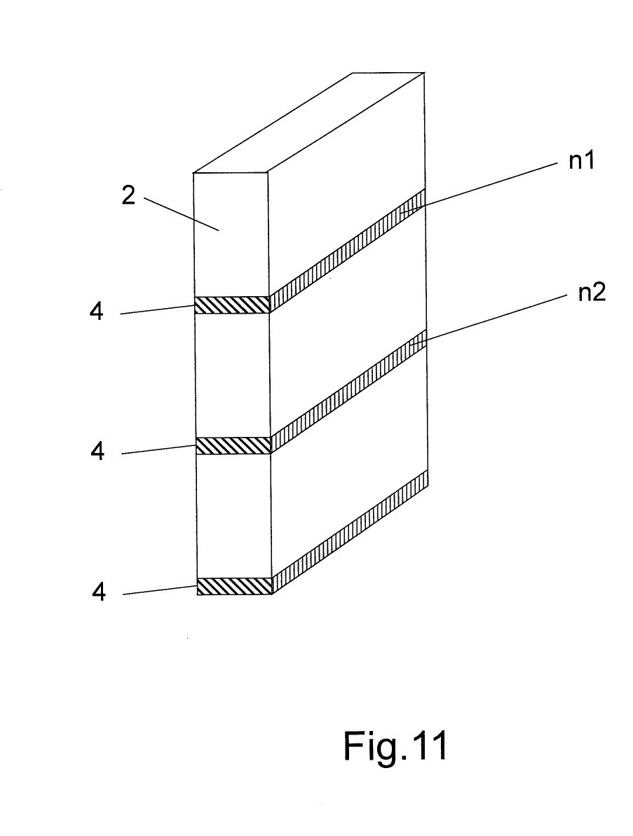

One of the challenges in the manufacture of PV windows is how to form the slits 4 with high aspect ratio, the ratio of h/w shown in FIG. 10. The current injection molding process normally has a limit for the aspect ratio of less than 5, but a higher ratio is desirable to improve the performance. FIG. 11 shows a solution that allows the slits 4 to be formed with a high aspect ratio, though the media of the slit 4 is not air but some other solid media with refractive index n2 less than n1.

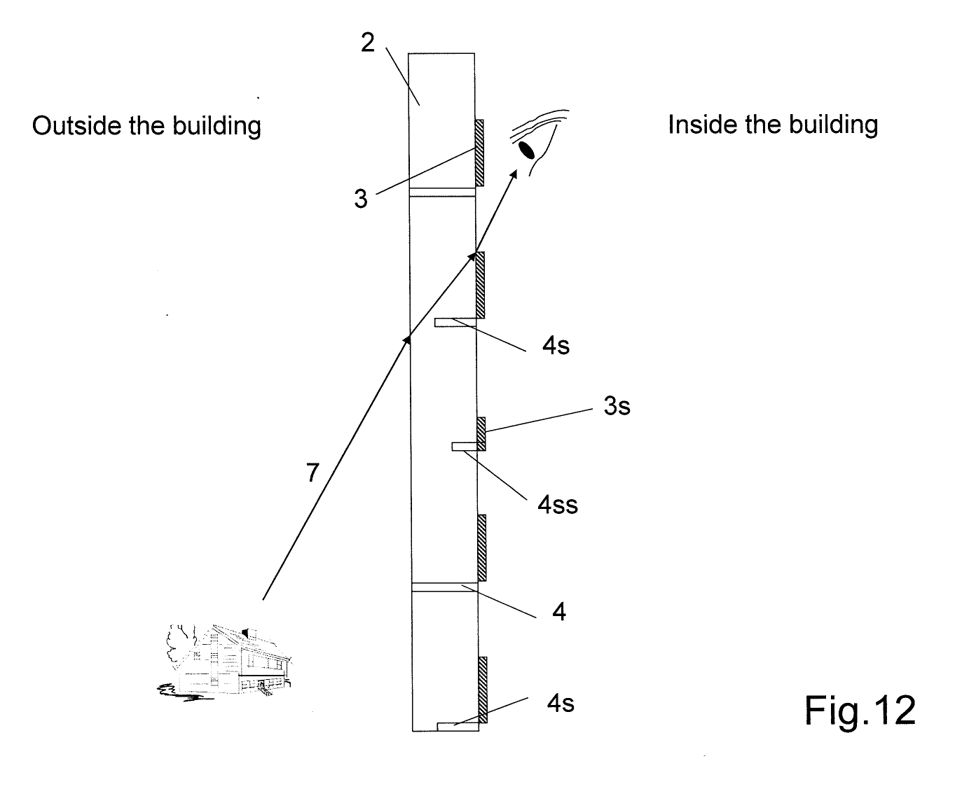

FIG. 12 shows a design that allows a person inside the building to be able to see objects outside even if the objects are well below the horizon. As it is shown in FIG. 12, by shortening the length of some of the air slits 4 (e.g., a first slit 4s and a second slit 4ss, wherein the first and second slits extend into the substrate 2 by first and second depths, respectively, that are different from one another) the light beam 7 that previously would be reflected by the air slits 4 (or the roughed surface of the air slit) now can pass through the window and enter the room/eyes of the observer. The number of slits having a shorter length per module and the actual length of the slits will vary depending on the requirements, and can correspond to a location of the slits within the substrate. The dimension, e.g., width of the solar cell strips can vary as well according to how the solar cell strips are matched to the slits (e.g., cell 32 is thinner than cell 3. It is possible for this to be constant although it depends on the required performance.

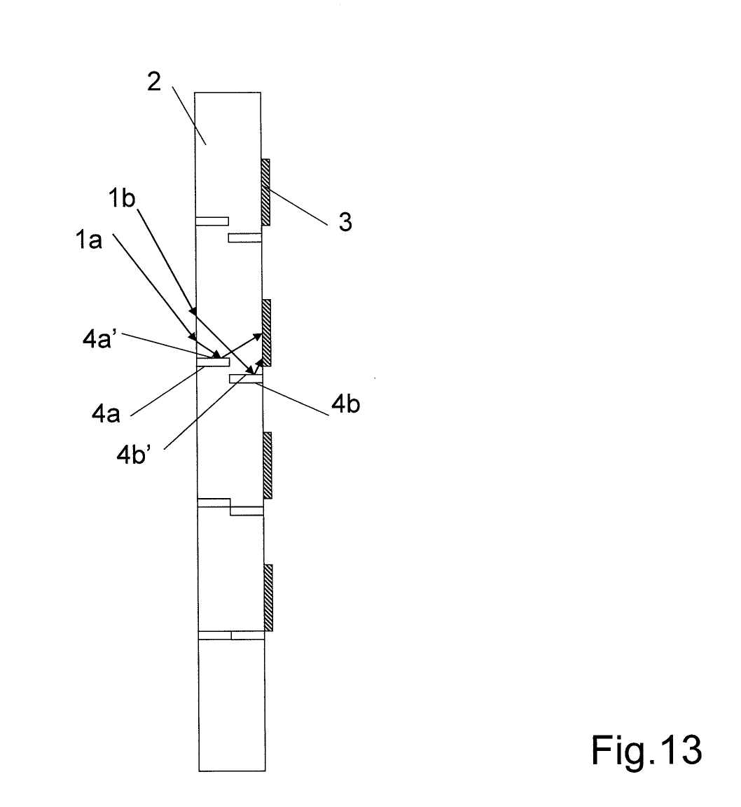

When a high aspect ratio of the slit 4 is needed it may go beyond the limit of the current molding ability. FIG. 13 shows a solution that can reduce the aspect ratio to half but still achieve the same performance by splitting one air slit into two slits 4a and 4b each having a reflecting surface 4a′ and 4b′, and fabricating each from opposite sides of the substrate 2. The two split shorter air slits 4a and 4b preferably are fabricated as close as possible, or aligned, in the vertical direction that is shown in the lower pair of slits arranged at the lower portion of the substrate. However, in certain embodiments the reflecting surfaces 4a′ and 4b′ of the respective slits may be offset from one another

### Preferred Embodiment

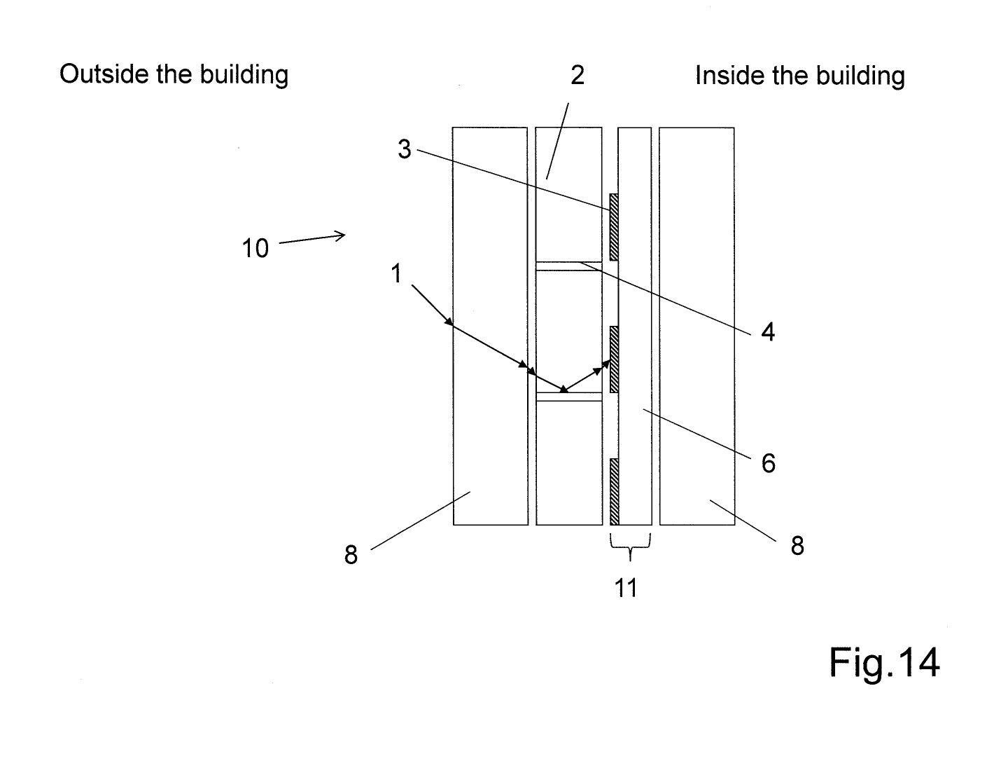

FIG. 14 shows how the optical element in accordance with the present invention could be incorporated into a solar module 10. The substrate 2 with plurality of slits 4 formed therein is laminated to the solar cell panel 11, which is formed by solar cells 3 and substrate 6, such that the substrate 2 is in optical contact with the solar cells 3 of the solar cell panel 11. This is then further laminated between protective glass sheets 8 (e.g., first and second outer substrates). A resin may be used to attach the protective glass sheets 8 to the substrate 2 and solar cell panel 11 to provide good protection from damage and water. The solar cell panel 11 with a plurality of solar cell strips requires the electrode on the solar cell 3 that is in contact with the substrate 2 be transparent.

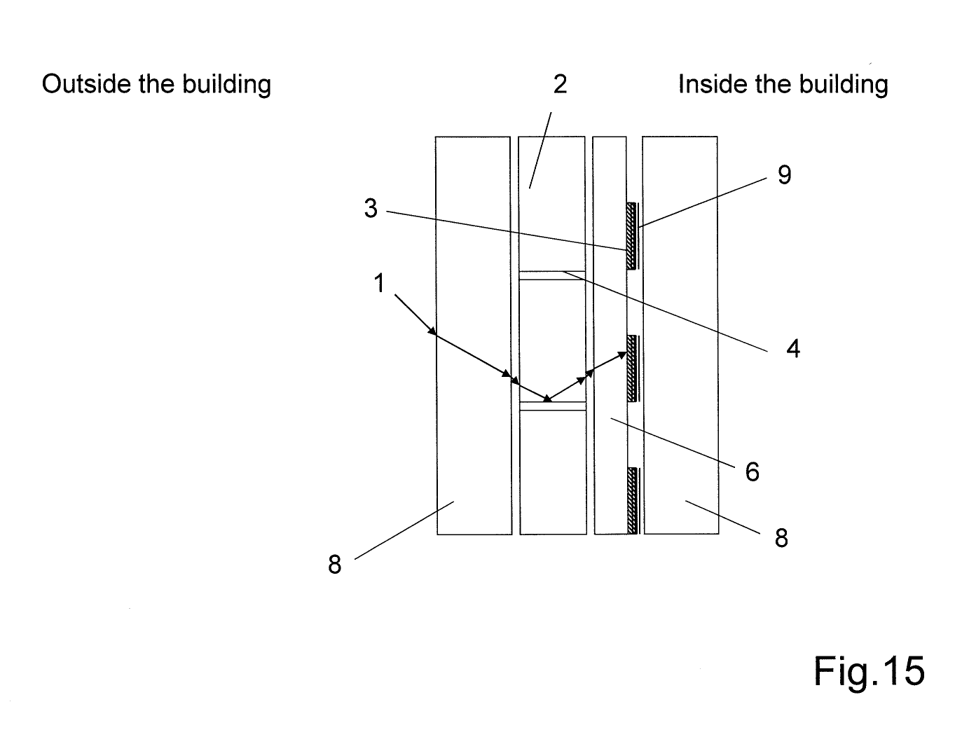

FIG. 15 shows a similar arrangement to that of FIG. 14, but the solar cell strips on the solar cell panel 11 have an opaque electrode 9 on the outer surface of the solar cell strips. In order for light to be absorbed by the solar cell 3, the solar cell panel 11 is arranged opposite to that of the device shown in FIG. 14. In this case there is a greater thickness of glass between the solar cell 3 and the substrate 2. This requires that the substrate 2 be carefully positioned in order for the light that undergoes TIR to be received correctly by the solar cell strips.

The optical feature can be any of the other shapes that are described in above embodiments. The gap between the elements can also be filled by transparent glue such as resin to reduce the surface reflection loss and gain the mechanical performance.

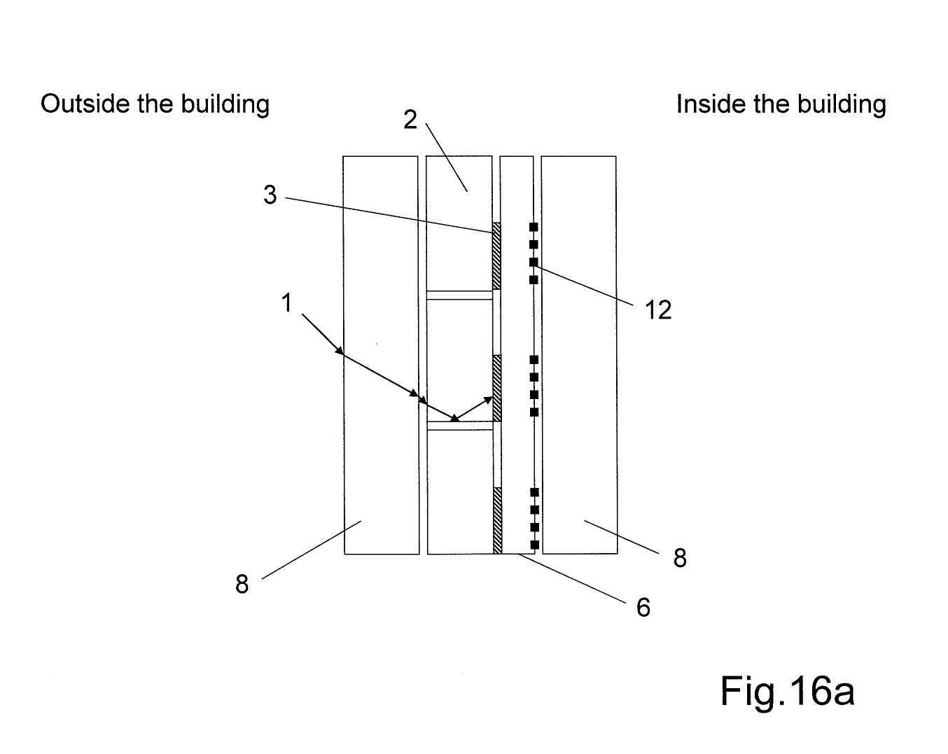

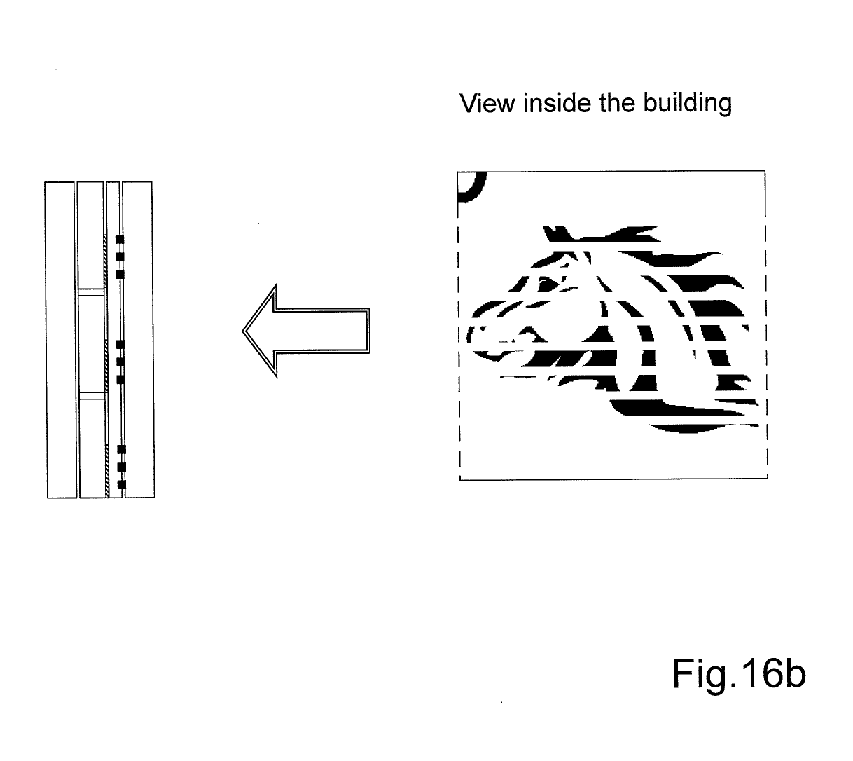

FIGS. 16a and 16b illustrate a feature wherein images may be displayed on the interior of a see-through PV window in accordance with the present invention. In this embodiment, on the side which faces ‘inside the building’, it is possible to create a decoration pattern 12 on the areas aligned with the solar cells 3 by either patterning the solar cells 3 in the desired manner, or coating the solar cells 3 with a reflective or absorbing coating on the correct side.

### INDUSTRIAL APPLICABILITY

1. Building Integrated PV (BIPV) field.

2. Solar powered mobile device.

3. Green houses.

4. Conservatories and sun roves.

1. A transparent solar concentrator, comprising:
a first light transmissive substrate;
a plurality of solar cells for receiving solar energy and converting the solar energy into electrical energy, the plurality of solar cells positioned relative to the first substrate;
a plurality of light redirecting elements arranged in the first light transmissive substrate, each of the plurality of light redirecting elements configured to direct light incident on a first side of the first light transmissive substrate to a respective one of the plurality of solar cells on an opposite side of the first light transmissive substrate.

2. The solar concentrator according to claim 1, wherein the first light transmissive substrate has a first refractive index, and the plurality of light redirecting elements have a second refractive index, the second refractive index being less than the first refractive index.

3. The solar concentrator according to claim 2, wherein each of the plurality of light redirecting elements comprise a strip or groove arranged in the first light transmissive substrate, the strip or groove filled with a medium having a refractive index corresponding to the second refractive index.

4. The solar concentrator according to claim 3, wherein the medium is air.

5. The solar concentrator according to claim 1, wherein the plurality of solar cells are formed as a plurality of photovoltaic strips, each strip spaced apart from an adjacent strip by a predetermined distance.

6. The solar concentrator according to claim 5, wherein each light redirecting element is aligned with a respective one of the photovoltaic strips.

7. The solar concentrator according to claim 1, further comprising a second light transmissive substrate, and the plurality of light redirecting elements are formed in the first light transmissive substrate, and the plurality of solar cells are positioned relative to the second light transmissive substrate.

8. The solar concentrator according to claim 1, wherein the plurality of light redirecting elements do not penetrate completely through the first light transmissive substrate.

9. The solar concentrator according to claim 1, wherein the plurality of light redirecting elements comprise a first part having a reflecting surface and a second part having a reflecting surface, wherein the reflecting surface of the first part is offset from the reflecting surface of the second part.

10. The solar concentrator according to claim 1, wherein the plurality of light redirecting elements have an upper surface and a lower surface, and the upper and lower surfaces are non-parallel to each other.

11. The solar concentrator according to claim 1, wherein at least two light redirecting elements are assigned to a respective one of the plurality of solar cells

12. The solar concentrator according to claim 1, wherein the plurality of solar cells comprise a first type of solar cell configured to convert light having a first range of wavelengths into electrical energy, and a second type of solar cell configured to convert light having a second range of wavelengths into electrical energy, the second range different from the first range.

13. The solar concentrator according to claim 1, wherein a reflecting surface of the plurality of light redirecting elements is not perpendicular to an outside light-receiving face of the first light transmissive substrate.

14. The solar concentrator according to claim 1, wherein the plurality of light redirecting elements comprise first and second light redirecting elements, the first light redirecting element extending into the first light transmissive substrate to a first depth, and the second light redirecting element extending into the at least one substrate to a second depth, wherein he first and second depths are different from one another.

15. The solar concentrator according to claim 14, wherein the first and second depths correspond to a location of the respective light redirecting element within the first light transmissive substrate.

16. The solar concentrator according to claim 1, wherein at least one surface of the light redirecting element comprises an optically flat surface and another surface of the light redirecting element comprises an optically rough surface.

17. The solar concentrator according to claim 1, further comprising first and second outer light transmissive substrates, wherein the first light transmissive substrate is arranged between the first and second outer light transmissive substrates.

18. A window system, comprising:
a first outer light transmissive substrate and a second outer light transmissive substrate; and
the solar concentrator according to claim 1, wherein the solar concentrator is arranged between the first and second outer light transmissive substrates.

19. The window system according to claim 18, wherein the plurality of solar cells are patterned to provide an image.

20. A method for creating a solar concentrator, comprising:
arranging a plurality of solar cells relative to a light transmissive substrate;
forming a plurality of light redirecting elements in the light transmissive substrate, wherein respective ones of the plurality of light redirecting elements are positioned relative to respective ones of the plurality of solar cells so as to direct light incident on a first side of the light transmissive substrate to a respective one of the plurality of solar cells on an opposite side of the light transmissive substrate.
